(19) United States
(12) Patent Application Publication
(10) Pub. No.: US 2020/0165724 A1
(43) Pub. Date: May 28, 2020

(54) APPARATUS AND METHOD FOR COATING SURFACE OF POROUS SUBSTRATE

(71) Applicant: LG CHEM, LTD., Seoul (KR)

(72) Inventors: Sang Joon PARK, Daejeon (KR); Jong Seok KIM, Daejeon (KR); Eun Jeong LEE, Daejeon (KR); Sung Su KIM, Daejeon (KR); Jae In LEE, Daejeon (KR); Eun Byurl CHO, Daejeon (KR)

(73) Assignee: LG CHEM, LTD., Seoul (KR)

(21) Appl. No.: 16/630,124

(22) PCT Filed: Jun. 22, 2018
(86) PCT No.: PCT/KR2018/007058

§ 371 Date: Jan. 10, 2020

(30) Foreign Application Priority Data
Jul. 12, 2017 (KR) 10-2017-0088402

(51) Int. Cl. C23C 16/455; C23C 16/54

(52) U.S. Cl. CPC C23C 16/45502; C03C 17/002; C23C 16/54

(57) ABSTRACT

The present invention relates to an apparatus and a method for coating a surface of a porous substrate, and according to one aspect of the present invention, there is provided an apparatus for coating a surface of a porous substrate having a first surface and a second surface opposite to the first surface, which comprises: a first supply part for supplying a source gas to the first surface of the porous substrate; a first pumping part for generating a air flow inside the porous substrate in the direction from the first surface of the porous substrate toward the second surface; a second supply part for supplying the source gas to the second surface of the porous substrate; a second pumping part for generating an air flow inside the porous substrate in the direction from the second surface of the porous substrate toward the first surface; and a substrate carrier for transporting the substrate.

This application is a 35 U.S.C. § 371 National Phase Entry Application from PCT/KR2018/007058, filed on Jun. 22, 2018, and designating the United States, which claims the benefit of priority based on Korean Patent Application No. 10-2017-0088402 filed on Jul. 12, 2017, the disclosures of which are incorporated herein by reference in their entirety.

### TECHNICAL FIELD

The present invention relates to an apparatus and a method for coating a surface of a porous substrate.

### BACKGROUND ART

As a method of forming a film on a substrate, there is, for example, an atomic layer deposition method.

The atomic layer deposition (ALD) is a technique for forming a film on a substrate based on the sequential use of chemical substances, which are usually in a gas phase, which is applied to various fields.

FIG. 1 is a schematic diagram showing a general atomic layer deposition apparatus (1), and particularly shows a spatial division type atomic layer deposition apparatus (1).

The atomic layer deposition apparatus (1) comprises a gas distribution plate (10) having a plurality of supply ports (11, 12, 13) and a transport device for transporting a substrate (20). The gas distribution plate (10) has precursor gas supply ports (11, 12) for supplying one or more precursor gases (precursor A, B) (also referred to as ‘source gas’) onto the substrate (20), and a purge gas supply port (13) for supplying a purge gas.

In addition, the atomic layer deposition method is advantageous for surface coating of pores in the porous substrate due to its high coatability. However, when the porous substrate becomes thick, supply and diffusion of the source gas into the pores, and purge and removal of reactive by-products are not smooth and thus uniform coating becomes difficult.

Specifically, depending on the pore size, the aspect ratio, or the surface characteristics of the porous substrate, the gas supply or diffusion into the pores may not be smooth, and accordingly, unevenness of the deposited thickness and composition may occur along the depth direction (thickness direction) of the porous substrate.

### DISCLOSURE

The present invention provides an apparatus and a method for coating a surface of a porous substrate which can uniformly coat the surface of the porous substrate.

According to one aspect of the present invention, there is provided an apparatus for coating a surface of a porous substrate having a first surface and a second surface opposite to the first surface, which comprises: a first supply part for supplying a source gas to the first surface of the porous substrate; a first pumping part for generating an air flow inside the porous substrate in the direction from the first surface of the porous substrate toward the second surface; a second supply part for supplying the source gas to the second surface of the porous substrate; a second pumping part for generating an air flow inside the porous substrate in the direction from the second surface of the porous substrate toward the first surface; and a substrate carrier for transporting the substrate.

Also, the first supply part and the first pumping part may be disposed to face each other on the basis of the substrate.

Furthermore, the second supply part and the second pumping part may be disposed to face each other on the basis of the substrate.

In addition, the first supply part and the second pumping part may be disposed in order along the transport direction of the substrate so as to face the first surface side of the substrate.

Also, the first pumping part and the second supply part may be disposed in order along the transport direction of the substrate so as to face the second surface side of the substrate.

Furthermore, the first supply part and the second supply part may be arranged in order along the transport direction of the substrate, and the first pumping part and the second pumping part may be arranged in order along the transport direction of the substrate.

In addition, the first pumping part and the second pumping part may be provided to form an air flow with the same pressure.

Also, the first pumping part and the second pumping part may be provided to form an air flow with different pressures.

Furthermore, the substrate carrier may have one or more openings for passing the air flow in at least some regions.

In addition, the substrate carrier may be provided so as to continuously transport the substrate upon passing through the first and second supply parts.

Alternatively, the substrate carrier may be provided to discontinuously transport the substrate upon passing through the first and second supply parts.

Also, the apparatus may further comprise a substrate reverse part for reversing the first surface and the second surface of the substrate passing through the first supply part.

At this time, the first supply part and the second supply part may be disposed on either the upper part or the lower part of the substrate in order along the transport direction of the substrate, and the first pumping part and the second pumping part may be disposed on the other part of the upper part or the lower part of the substrate in order along the transport direction of the substrate.

In addition, according to still another aspect of the present invention, there is provided a method for coating a surface of a porous substrate by generating an air flow inside pores in the porous substrate having a first surface and a second surface opposite to the first surface, which comprises steps of: transporting the porous substrate; supplying and diffusing a source gas in the direction from the first surface of the porous substrate toward the second surface, and removing reactive by-products and the remaining source after the reaction; and supplying and diffusing the source gas in the direction from the second surface of the porous substrate toward the first surface, and removing reactive by-products and the remaining source after the reaction.

### Advantageous Effects

As described above, the apparatus and the method for coating a surface of a porous substrate related to at least one embodiment of the present invention have the following effects.

Supply and diffusion of the source gas are smoothly performed on both surfaces of the porous substrate by allowing the direction where the source gas is supplied and the air flow direction formed inside the porous substrate to sequentially pass through different spaces along the transport direction of the porous substrate, whereby the unevenness of the deposited thickness and composition can be improved.

Furthermore, the degree of deposition on both surfaces (front surface, back surface) of the porous substrate can be optionally controlled.

### BRIEF DESCRIPTION OF DRAWINGS

FIG. 1 is a schematic diagram showing a general atomic layer deposition apparatus.

FIG. 2 is a schematic diagram showing a surface coating apparatus of a porous substrate related to a first embodiment of the present invention.

FIG. 3 is a schematic diagram showing a surface coating apparatus of a porous substrate related to a second embodiment of the present invention.

FIG. 4 is an enlarged diagram of Part A in FIG. 3.

FIG. 5 is an enlarged diagram of Part B in FIG. 3.

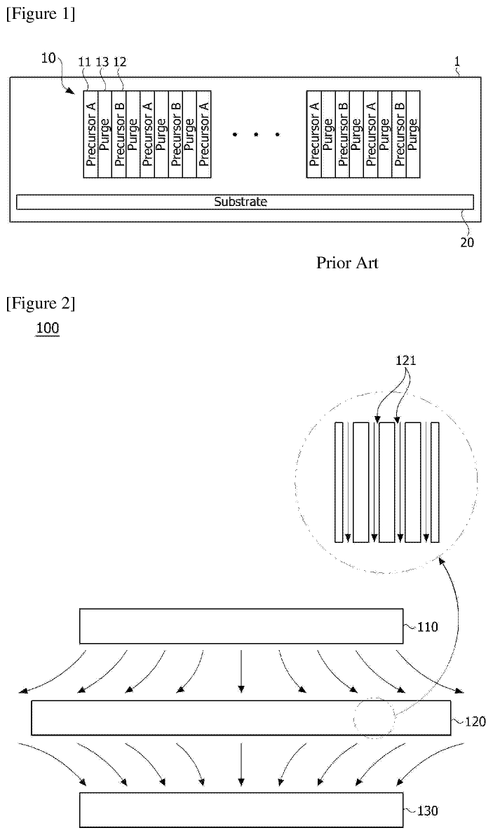

### MODE FOR INVENTION

Hereinafter, an apparatus and a method for coating a surface of a porous substrate according to one embodiment of the present invention will be described in detail with reference to the accompanying drawings.

In addition, the same or similar reference numerals are given to the same or corresponding components regardless of reference numerals, of which redundant explanations will be omitted, and for convenience of explanation, the size and shape of each constituent member as shown may be exaggerated or reduced.

In this document, the surface coating apparatus of a porous substrate (hereinafter, also referred to as ‘coating apparatus’) may be an atomic layer deposition apparatus, but is not limited thereto, which can also be applied to various deposition methods in which coating is performed by formation of an air flow, for example, chemical vapor deposition, molecular layer deposition, or deposition by a combination thereof.

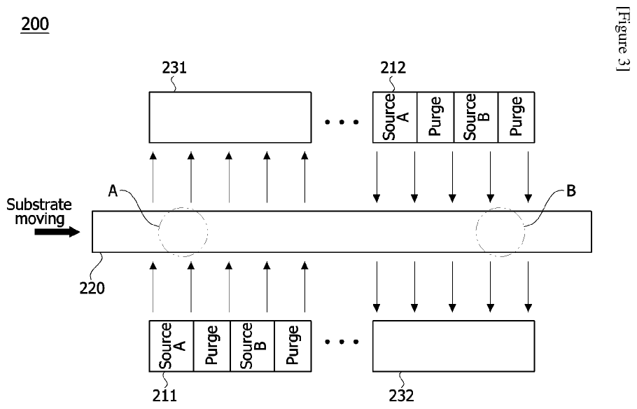

FIG. 2 is a schematic diagram showing a surface coating apparatus (100) of a porous substrate related to a first embodiment of the present invention.

The coating apparatus (100) is an apparatus for coating a surface of a porous substrate having a first surface and a second surface opposite to the first surface, which comprises: a source gas supply part (110) for supplying a source gas to the first surface of the porous substrate (20) and a source gas pumping part (130) for generating an air flow in the porous substrate interior (pores, 121) in the direction from the first surface of the porous substrate (120) toward the second surface.

Accordingly, the source gas is injected toward the first surface side of the porous substrate (120), and simultaneously the air flow directed from the first surface side toward the second surface side is generated in the pores of the porous substrate (120) through the source gas pumping part (130), whereby injection and diffusion of the source gas into the inside of the porous substrate (120) are smooth.

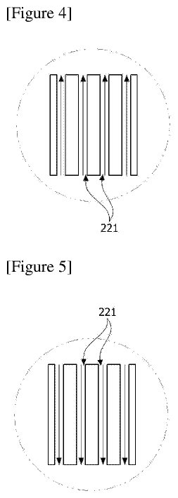

FIG. 3 is a schematic diagram showing a surface coating apparatus (200) of a porous substrate related to a second embodiment of the present invention, FIG. 4 is an enlarged diagram of Part A in FIG. 3, and FIG. 5 is an enlarged diagram of Part B in FIG. 3.

The coating apparatus (200) related to the second embodiment is an apparatus for coating a surface of a porous substrate having a first surface (e.g., front surface) and a second surface (e.g., back surface) opposite to the first surface.

The coating apparatus (200) comprises a first supply part (211) for supplying a source gas to a first surface of a porous substrate (200) and a first pumping part (231) for generating an air flow inside the porous substrate (220) in the direction from the first surface of the porous substrate (220) toward the second surface.

The coating apparatus (200) also comprises a second supply part (212) for supplying a source gas to the second surface of the porous substrate (220) and a second pumping part (232) for generating an air flow inside the porous substrate (220) in the direction from the second surface of the porous substrate (220) toward the first surface.

The coating apparatus (200) also comprises a substrate carrier (not shown) for transporting the substrate (220). At this time, the substrate carrier has one or more openings for passing the air flow in at least some regions. For example, the substrate carrier may also be configured in the form of a mesh or grill having a predetermined aperture ratio. Alternatively, the substrate carrier may also be configured in a roll-to-roll manner to comprise a plurality of guide rolls. In such a structure, in order to form openings for passing the air flow, the roll-to-roll apparatus may also be configured so as to support both side edges of the substrate in the width direction.

On the other hand, on the basis of FIG. 3, the region where the first pumping part (231) and the second supply part (212) are disposed may be referred to as the upper part of the substrate (220), and the region where the first supply part (211) and the second pumping part (232) are disposed may be referred to as the lower part of the substrate (220).

The first and second supply parts (211, 212) are provided so as to inject the source gas onto the substrate, which comprise one or more source gas (source A, source B) injection ports and purge gas injection ports.

Specifically, each of the supply parts (211, 212) may comprise pretreatment gas injection ports, source gas injection ports, and purge gas injection ports. For example, in the supply part, a pretreatment gas injection port, a first precursor (source A) injection port, a purge gas injection port, a second precursor (source B) injection port, and a purge gas injection port may be arranged. In addition, the pretreatment gas injection port may have a plurality of different gas injection ports. Furthermore, plasma or organic vapor may be supplied through the pretreatment gas injection port.

Also, the first supply part (211) and the first pumping part (231) may be disposed to face each other on the basis of the substrate (220). For example, when the source gas is injected to the first surface side of the substrate through the first supply part (211), the first pumping part (231) generates the air flow directed from the first surface toward the second surface in pores (221) inside the porous substrate, whereby the coating can be achieved inside the pores.

Furthermore, the second supply part (212) and the second pumping part (232) may be disposed to face each other on the basis of the substrate. For example, when the source gas is injected to the second surface side of the substrate (220) through the second supply part (212), the second pumping part (232) generates the air flow directed from the second surface toward the first surface in pores (221) inside the porous substrate, whereby the coating can be achieved inside the pores.

In addition, the first supply part (211) and the second pumping part (232) may be disposed in order along the transport direction of the substrate (220) so as to face the first surface side of the substrate (e.g., the lower part of the substrate), and the first pumping part (231) and the second supply part (212) may be disposed in order along the transport direction of the substrate (220) so as to face the second surface side of the substrate (e.g., the upper part of the substrate).

Also, the first supply part (211) and the second supply part (212) may be arranged in order along the transport direction of the substrate, and for example, the first supply part (211) may be disposed on the lower part of the substrate, the second supply part (212) may be disposed on the upper part of the substrate and vice versa. Furthermore, the first pumping part (231) and the second pumping part (232) may be arranged in order along the transport direction of the substrate, and for example, the first pumping part (231) may be disposed on the upper part of the substrate, the second pumping part (232) may be disposed on the lower part of the substrate and vice versa.

Referring to FIGS. 3 to 5, supply and diffusion of the source gas are smoothly performed on both surfaces (first surface and second surface) of the porous substrate (200) by allowing the direction where the source gas is supplied and the air flow direction (see arrows in FIGS. 4 and 5) formed inside the porous substrate to sequentially pass through different spaces along the transport direction of the porous substrate (220).

On the other hand, the first pumping part (231) and the second pumping part (232) may be provided to form an air flow with the same pressure. Alternatively, the first pumping part (231) and the second pumping part (232) may also be provided to form an air flow with different pressures. Thus, the degree of deposition of the porous substrate (220) on both surfaces (front surface, back surface) can be optionally controlled.

The substrate carrier may also be provided to transport a continuous substrate. The continuous substrate may be a web.

While the example in which the supply part and the pumping part are arranged so that the directions of the air flows applied to the porous substrate (220) cross during traveling of the porous substrate (220) has been explained so far, the present invention is not limited to such a manner.

The substrate carrier may also be provided to transport a discontinuous substrate. The discontinuous substrate may be a wafer or glass. At this time, the coating apparatus (200) may further comprise a substrate reverse part (not shown) for reversing the first surface and the second surface of the substrate passing through the first supply part (211).

At this time, the first supply part (211) and the second supply part (212) may be disposed in order along the transport direction of the substrate on either the upper part or the lower part of the substrate. For example, the first supply part (211) and the second supply part (212) may be disposed together on the upper part of the substrate or on the lower part.

Similarly, the first pumping part (231) and the second pumping part (232) may be disposed in order along the transport direction of the substrate (220) on the other part of the upper part or the lower part of the substrate.

For example, the first pumping part (231) and the second pumping part (232) may be disposed together on the upper part of the substrate (220) or on the lower part. Of course, when the first and second supply parts (211, 212) are disposed on the upper part of the substrate (220), the first pumping part (231) and the second pumping part (232) may be disposed on the lower part of the substrate (220).

Also, the first supply part (211) and the first pumping part (231) may be arranged to face each other on the basis of the substrate (220), and the second supply part (212) and the second pumping part (232) may be arranged to face each other on the basis of the substrate (220).

The coating method using the coating apparatus (200) having the above structure is as follows.

The coating method is a method for coating a surface of a porous substrate by generating an air flow inside pores in the porous substrate having a first surface and a second surface opposite to the first surface, which comprises steps of: transporting the porous substrate; supplying and diffusing a source gas in the direction from the first surface of the porous substrate toward the second surface, and removing reactive by-products and the remaining source after the reaction; and supplying and diffusing the source gas in the direction from the second surface of the porous substrate toward the first surface, and removing reactive by-products and the remaining source after the reaction.

For example, the surface coating method of a porous substrate is a method for coating a surface of a porous substrate having a first surface and a second surface opposite to the first surface, which comprises steps of: transporting the porous substrate; supplying and diffusing a source gas to the first surface of the porous substrate; and generating an air flow inside the porous substrate in the direction from the first surface of the porous substrate toward the second surface.

In addition, the method comprises steps of: supplying and diffusing a source gas to the second surface of the porous substrate; and generating an air flow inside the porous substrate in the direction from the second surface of the porous substrate toward the first surface.

The preferred embodiments of the present invention as described above are disclosed for exemplary purpose, where those skilled in the art having ordinary knowledge for the present invention can make various corrections, modifications and additions within idea and scope of the present invention, and such a correction, modification and addition should be considered as falling within the scope of the following claims.

### INDUSTRIAL APPLICABILITY

According to the surface coating apparatus and method of the porous substrate related to at least one embodiment of the present invention, supply and diffusion of the source gas are smoothly performed on both surfaces of the porous substrate, whereby the unevenness of the deposited thickness and composition can be improved.

1. An apparatus for coating a surface of a porous substrate having a first surface and a second surface opposite to the first surface, which comprises:
a first supply part for supplying a source gas to the first surface of the porous substrate;
a first pumping part for generating an air flow inside the porous substrate in the direction from the first surface of the porous substrate toward the second surface;
a second supply part for supplying the source gas to the second surface of the porous substrate;
a second pumping part for generating an air flow inside the porous substrate in the direction from the second surface of the porous substrate toward the first surface; and
a substrate carrier for transporting the porous substrate.

2. The apparatus for coating a porous substrate according to claim 1,
wherein the first supply part and the first pumping part are arranged to face each other with the porous substrate interposed therebetween.

3. The apparatus for coating a porous substrate according to claim 1,
wherein the second supply part and the second pumping part are arranged to face each other with the porous substrate interposed therebetween.

4. The apparatus for coating a porous substrate according to claim 1,
wherein the first supply part and the second pumping part are arranged in order along a transporting direction of the porous substrate so as to face the first surface of the porous substrate.

5. The apparatus for coating a porous substrate according to claim 1,
wherein the first pumping part and the second supply part are arranged in order along a transporting direction of the porous substrate so as to face the second surface of the porous substrate.

6. The apparatus for coating a porous substrate according to claim 1,
wherein the first supply part and the second supply part are arranged in order along a transporting direction of the porous substrate, and
the first pumping part and the second pumping part are arranged in order along a transporting direction of the porous substrate.

7. The apparatus for coating a porous substrate according to claim 1,
wherein the air flow generated from the first pumping part and the air flow generated from the second pumping part have the same pressure.

8. The apparatus for coating a porous substrate according to claim 1,
wherein the air flow generated from the first pumping part and air flow generated from the second pumping part have different pressures.

9. The apparatus for coating a porous substrate according to claim 1,
wherein the first supply part comprises pretreatment gas injection ports, source gas injection ports and purge gas injection ports.

10. The apparatus for coating a porous substrate according to claim 9,
wherein plasma or organic vapor is supplied through the pretreatment gas injection ports.

11. The apparatus for coating a porous substrate according to claim 1,
wherein the substrate carrier has one or more openings in at least some regions for passing the air flow.

12. The apparatus for coating a porous substrate according to claim 1,
wherein the substrate carrier is provided for a continuous transporting of the porous substrate.

13. The apparatus for coating a porous substrate according to claim 1,
wherein the substrate carrier is provided for a discontinuous transporting of the porous substrate.

14. The apparatus for coating a porous substrate according to claim 13,
further comprising a substrate reverse part for reversing the first surface and the second surface of the porous substrate after passing through the first supply part.

15. The apparatus for coating a porous substrate according to claim 14,
wherein the first supply part and the second supply part are arranged in order along a transporting direction of the porous substrate on either the first surface or the second surface of the porous substrate, and
the first pumping part and the second pumping part are arranged in order along a transporting direction of the porous substrate on the other part of the first surface or the second surface of the porous substrate.

16. A method for coating a surface of a porous substrate by generating an air flow inside pores in the porous substrate having a first surface and a second surface opposite to the first surface, which comprises steps of:
transporting the porous substrate;
supplying and diffusing a source gas in a direction from the first surface of the porous substrate toward the second surface, and removing reactive by-products and the remaining source gas after the reaction; and
supplying and diffusing the source gas in a direction from the second surface of the porous substrate toward the first surface, and removing reactive by-products and the remaining source gas after the reaction.
